(19) United States
(12) Patent Application Publication
(10) Pub. No.: US 2020/0393296 A1
(43) Pub. Date: Dec. 17, 2020

(54) TUNABLE GRAPHENE DETECTOR FOR BROADBAND TERAHERTZ DETECTION, IMAGING, AND SPECTROSCOPY

(71) Applicant: MASSACHUSETTS INSTITUTE OF TECHNOLOGY, Cambridge, MA (US)

(72) Inventor: Long JU, Cambridge, MA (US)

(73) Assignee: MASSACHUSETTS INSTITUTE OF TECHNOLOGY, Cambridge, MA (US)

(21) Appl. No.: 16/901,419

(22) Filed: Jun. 15, 2020

Related U.S. Application Data
(60) Provisional application No. 62/862,067, filed on Jun. 15, 2019.

(51) Int. Cl. G01J 1/44; G01J 3/28; G01J 3/02; H01L 31/028; H01L 31/112

(52) U.S. Cl. CPC G01J 1/44; G01J 3/28; G01J 2001/444; H01L 31/028; H01L 31/112; G01J 3/027

(57) ABSTRACT

Disclosed are systems, methods, and structures including a tunable graphene detector for broadband terahertz detection, imaging, and spectroscopy.

### CROSS-REFERENCE TO RELATED APPLICATION

This application claims the benefit of U.S. Provisional Patent Application Ser. No. 62/862,067 filed Jun. 15, 2019, which is incorporated by reference herein in its entirety.

### TECHNICAL FIELD

This disclosure relates generally to the detection of terahertz electromagnetic radiation and more particularly to a tunable graphene detector for broadband terahertz detection, imaging, and spectroscopy.

### BACKGROUND

As will be readily appreciated by those skilled in the art, the ability to reliably detect terahertz electromagnetic radiation (loosely defined as the 0.1˜15 THz frequency range) is of profound contemporary importance when applied to important applications including medical imaging and diagnosis, chemical analysis of pharmaceuticals and environmental pollutants, and security screening. Given this importance, improved broadband terahertz detectors and systems, methods, and structures constructed therefrom would represent a welcome addition to the art.

### SUMMARY

An advance is made in the art according to aspects of the present disclosure directed to tunable graphene detectors for broadband terahertz detection, imaging, and spectroscopy.

In sharp contrast to the prior art, tunable graphene detectors according to aspects of the present disclosure employ sharp THz absorption resonances of the graphene in conjunction with applied magnetic field(s) and electrical potential(s) to provide a THz detector that advantageously and surprisingly does not suffer from slow response time(s) or narrow detection range(s) that plague the prior art.

Advantageously, tunable graphene detectors according to the present disclosure exhibit a narrow absorption resonance in magnetic fields as low as 0.4 Tesla, which those skilled in the art will readily understand and appreciate is well below field strength(s) 1.5 Tesla) exhibited by cheap, permanent Rare Earth (i.e., Neodymium) magnets. Further enhancements to tunable graphene detectors according to the present disclosure are realized by micro-fabricated antenna structures and lens(es) (i.e., silicon) to further collect/focus light to be detected. Finally, a motorized stage provides for great tunability of the permanent magnet, while an additional or alternative electromagnetic structure further enhances its tunability.

This SUMMARY is provided to briefly identify some aspect(s) of the present disclosure that are further described below in the DESCRIPTION. This SUMMARY is not intended to identify key or essential features of the present disclosure nor is it intended to limit the scope of any claims.

The term “aspect” is to be read as “at least one aspect”. The aspects described above, and other aspects of the present disclosure are illustrated by way of example(s) and not limited in the accompanying drawing.

### BRIEF DESCRIPTION OF THE DRAWING

A more complete understanding of the present disclosure may be realized by reference to the accompanying drawing in which:

FIG. 1 shows a schematic diagram depicting a illustrative tunable graphene detector structure and operational environment according to aspects of the present disclosure;

FIG. 2(A) shows a schematic energy-level diagram depicting optical transitions between Landau levels for graphene according to aspects of the present disclosure;

FIG. 2(B) shows a graph illustrating a single absorption peak of graphene inter Landau level transition used to read out intensity of incident beam at the same light frequency according to aspects of the present disclosure;

FIG. 3 shows a schematic diagram depicting an alternative illustrative tunable graphene detector structure and operational environment according to aspects of the present disclosure;

FIG. 4 shows a schematic diagram depicting a top-view of an illustrative tunable graphene detector structure exhibiting a Corbino geometry according to aspects of the present disclosure;

FIG. 5 shows a schematic cross-sectional view of an illustrative tunable graphene detector of FIG. 4 in which this cross-sectional view is taken along a dotted-line of that FIG. 4—according to aspects of the present disclosure;

FIG. 6 shows a schematic diagram depicting an illustrative tunable graphene detector structure employing a permanent magnet according to aspects of the present disclosure;

FIG. 7 shows a schematic diagram depicting an illustrative tunable graphene detector structure employing a permanent magnet of FIG. 6 wherein the permanent magnet is moved relative to the graphene detector via cryogenic actuator according to aspects of the present disclosure;

FIG. 8 shows a schematic diagram depicting an illustrative tunable graphene detector structure employing a permanent magnet and tunable coil magnet according to aspects of the present disclosure;

FIG. 9 shows a schematic block diagram of an illustrative spectrometer employing a tunable graphene THz detector according to aspects of the present disclosure.

FIG. 10 shows a plot of Signal (a.u.) vs. wavenumber (cm⁻¹) illustrating Fermi level inside a bandgap according to aspects of the present disclosure;

FIG. 11 shows a plot of Signal (a.u.) vs. wavenumber (cm⁻¹) illustrating Fermi level between −1 and −2 inside a bandgap according to aspects of the present disclosure;

FIG. 12 shows a plot of Signal (a.u.) vs. wavenumber (cm⁻¹) illustrating Fermi level between −2 and −3 inside a bandgap according to aspects of the present disclosure;

FIG. 13 shows a plot of Signal (a.u.) vs. wavenumber (cm⁻¹) illustrating Fermi level between −3 and −4 inside a bandgap according to aspects of the present disclosure;

FIG. 14 shows a plot of normalized conductance (a.u.) vs. Gate (V) illustrating the development of Landau levels at magnetic field levels less than 1 Tesla according to aspects of the present disclosure;

FIG. 15 shows a pair of plots of photocurrent (a.u.) vs. wave number (cm⁻¹) for v=−2 and v=10 according to aspects of the present disclosure;

FIG. 16 shows a pair of plots of (upper) photocurrent (a.u.) vs. wave number (cm⁻¹) and (lower) wave number (cm⁻¹) vs. B^{1/2} (T^{1/2}) according to aspects of the present disclosure; and

FIG. 17 shows a plot of photocurrent (a.u.) vs. W (cm⁻¹) illustrating the nearly Lorentzian linewidth FWHM˜1.6 meV, limited by lifetime, not disorders according to aspects of the present disclosure.

### DETAILED DESCRIPTION

The following merely illustrates the principles of the disclosure. It will thus be appreciated that those skilled in the art will be able to devise various arrangements which, although not explicitly described or shown herein, embody the principles of the disclosure and are included within its spirit and scope. More particularly, while numerous specific details are set forth, it is understood that embodiments of the disclosure may be practiced without these specific details and in other instances, well-known circuits, structures and techniques have not been shown in order not to obscure the understanding of this disclosure.

Furthermore, all examples and conditional language recited herein are principally intended expressly to be only for pedagogical purposes to aid the reader in understanding the principles of the disclosure and the concepts contributed by the inventor(s) to furthering the art and are to be construed as being without limitation to such specifically recited examples and conditions.

Moreover, all statements herein reciting principles, aspects, and embodiments of the disclosure, as well as specific examples thereof, are intended to encompass both structural and functional equivalents thereof. Additionally, it is intended that such equivalents include both currently-known equivalents as well as equivalents developed in the future, i.e., any elements developed that perform the same function, regardless of structure.

Thus, for example, it will be appreciated by those skilled in the art that the diagrams herein represent conceptual views of illustrative structures embodying the principles of the disclosure.

In addition, it will be appreciated by those skilled in art that certain methods according to the present disclosure may represent various processes which may be substantially represented in computer readable medium and so controlled and/or executed by a computer or processor—whether or not such computer or processor is explicitly shown.

In the claims hereof any element expressed as a means for performing a specified function is intended to encompass any way of performing that function including, for example, a) a combination of circuit elements which performs that function or b) software in any form, including, therefore, firmware, microcode or the like, combined with appropriate circuitry for executing that software to perform the function. The invention as defined by such claims resides in the fact that the functionalities provided by the various recited means are combined and brought together in the manner which the claims call for. Applicant thus regards any means which can provide those functionalities as equivalent as those shown herein. Finally, and unless otherwise explicitly specified herein, the drawings are not drawn to scale.

By way of some additional background, we begin by noting that the spectrum range between well-established electronic and optical frequencies—known as the THz range—is of great importance to many scientific and technological applications including medical imaging and diagnosis, chemical analysis of pharmaceuticals and environmental pollutants, and security screening.

More particularly—and as will be readily appreciated by those skilled in the art—THz radiation may be employed to image different biological tissue(s). Of particular advantage, THz radiation exhibits lower photon energy than X-rays thereby avoiding tissue and DNA damage produced by X-rays—while simultaneously providing greater resolution than ultrasound imaging technologies.

Additionally, THz radiation—when employed in a broadband spectrometer—may differentiate chemically identical—but structurally different polymorphs—thereby providing both economical and reliable quality control in pharmaceutical development and manufacture as well as low level detection and identification of chemical constituents of environmental interest.

Finally, since hazardous and/or energetic materials (i.e., explosives) exhibit “fingerprints” in the range of THz radiation—their detection and identification is made possible by THz techniques.

Given these—and other considerations—improved THz detectors and in particular tunable THz detectors along with systems, methods, and structures constructed therefrom are of great contemporary interest and importance.

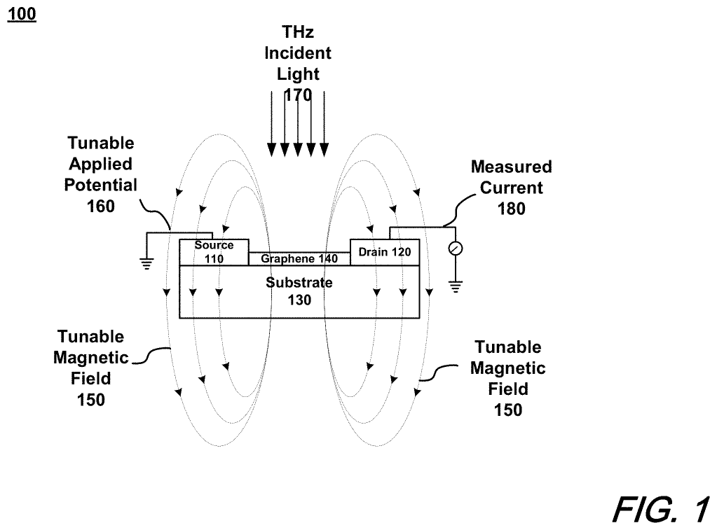

Turning now to FIG. 1, there is shown a schematic diagram depicting a simplified, illustrative tunable THz detector structure and arrangement according to aspects of the present disclosure. As will become readily apparent to those skilled in the art, detector structures according to aspects of the present disclosure may advantageously be integrated into imaging and spectrum analysis systems and methods—providing informational value beyond that which is currently possible with existing systems and methods.

With continued reference to that FIG. 1, shown therein is an illustrative tunable THz detector structure 100 including a substrate 130 having formed/deposited thereon/therein a source electrode 110, a drain electrode 120, and a graphene region 140 shown interposed between the source electrode and drain electrode.

Operationally, the tunable THz structure is exposed to a tunable (adjustable), perpendicular, magnetic field 150 while an electrical potential—which may also be tunable 160—is applied across the source and drain. When so operated, and the device—and in particularly the graphene region, is illuminated by THz radiation 170—a change in current across the source/drain may be measured 180. Accordingly, a multi-tunable THz detector structure is produced.

At this point those skilled in the art will readily appreciate that this simplified, illustrative schematic representation of a tunable THz detector structure may advantageously be fabricated using any of a number of convenient fabrication techniques/technologies/materials known in the art. As we shall show further, structural variations are contemplated as well.

Those skilled in the art will know and appreciate that graphene is a form (allotrope) of carbon in the form of a two-dimensional, hexagonal lattice in which one atom forms each vertex. As employed in structures according to the present disclosure, a graphene monolayer is preferably used and when placed in a perpendicular magnetic field, electrons in the graphene form different energy levels known as Landau levels (LLs).

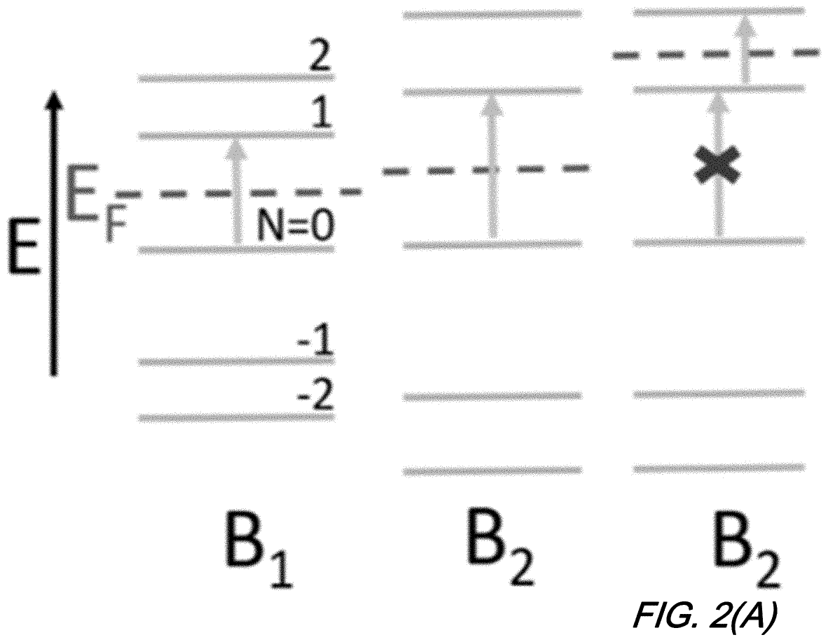

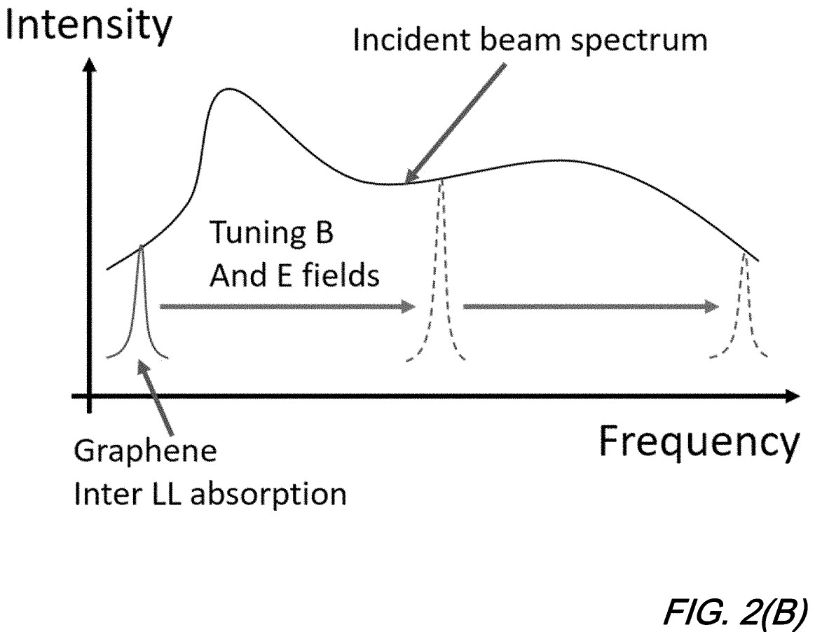

Turning now to FIG. 2(A), there is shown a schematic energy level diagram of graphene illustrating optical transitions between the Landau levels. As is known, graphene is an electrical insulator when Fermi level E_{F} is situated between the Landau levels. When exposed to appropriate incident photons—such as those in a very narrow THz range—electrons in Landau levels below the Fermi level may be excited to a Landau level above the Fermi level, thereby resulting in the graphene becoming electrically conductive. When employed in structures according to the present disclosure, such excitation may produce a detectable, electrical current between electrodes to which an electrical potential has been applied.

As will be further appreciated by those skilled in the art, the transition from insulator to conductor for graphene results from an optical transition in a very narrow absorption resonance in the THz range, and its energy is proportional to where B is the applied magnetic field. Additionally, transitions having different energies may be switched on/off by producing a shift in E_{F}.

We note that all the levels below E_{F} are filled with electrons while all the levels above E_{F} are empty. The optical transition is allowed only when the initial state and the final state are separated by the Fermi level E_{F}. By shifting E_{F} using a gate electric field in a field effect transistor device, we can selectively block or enable specific inter Landau level transitions. Due to the non-equal distance nature of Landau levels in graphene, these transitions have different energies. Therefore, we may advantageously tune the sensitive frequency of the detector by an external electric field—together with a magnetic field.

Turning our attention now to FIG. 2(B), there is shown a plot of Intensity vs. Frequency illustrating that a single absorption peak of graphene inter Landau level transition is used to read out the intensity of an incident beam at the same light frequency. The intensity at different frequencies in the whole spectrum range is mapped out by shifting the inter LL absorption peak by tuning the electric field and magnetic field.

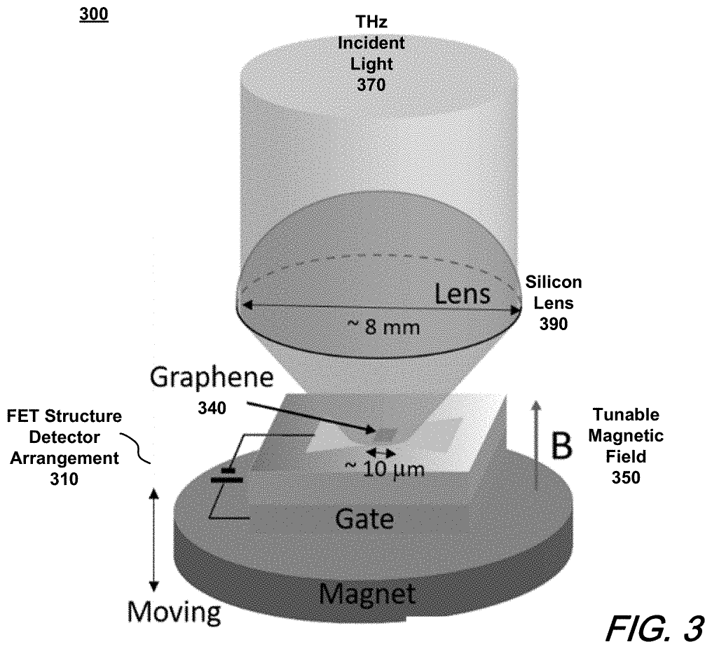

With reference now to FIG. 3, there is shown in schematic form an alternative illustrative arrangement of a tunable THz detector structure according to aspects of the present disclosure. As may be observed from that figure, graphene 340 is fabricated onto a field-effect-transistor (FET) like structure 310 including a gate structure, electrode structures, and substrate. A permanent—i.e., rare earth magnet is employed to provide a tunable magnetic field 350. Such “tunability”, may advantageously be achieved by physically moving the magnet relative to the tunable FET detector arrangement. Also shown in this figure is THz incident light 370 directed to the tunable FET detector arrangement—and in particular the graphene 340—via a silicon lens 390. As will be understood and appreciated, such lens directs the incident light to the graphene region where it may undergo optical transitions previously described and thereafter switching from electrical insulator to electrical conductor. In this illustrative embodiment the width of the graphene is approximately 10 μm and the diameter of the silicon lens is approximately 8 mm—which are only illustrative. Different dimensions are of course possible and contemplated by this disclosure. We note at this point that the use of a silicon lens is shown due—in part—to its convenient fabrication from known silicon techniques and methodologies that are advantageously compatible with the fabrication of the tunable FET structure. Those skilled in the art will readily understand and appreciate that the construction of general FET structures advantageously employ well known materials and methodologies as well.

Operationally, the THz detector structure illustrated in FIG. 3 achieves magnetic field tuning by moving the magnet relative to the THz detector structure. As we shall show and describe, such movement may be performed by an electric motor or an alternative linear actuator mechanism. Note that a shift in E_{F} is performed by applying an electrical voltage on the gate to modulate electron density. As such, a tunable structure where both electron density and magnetic field are tunable results in a tunable THz detector in the very broad ˜1-15 THz range. Finally, the silicon lens shown illustratively in the figure directs more light to the graphene to permit maximum detectivity.

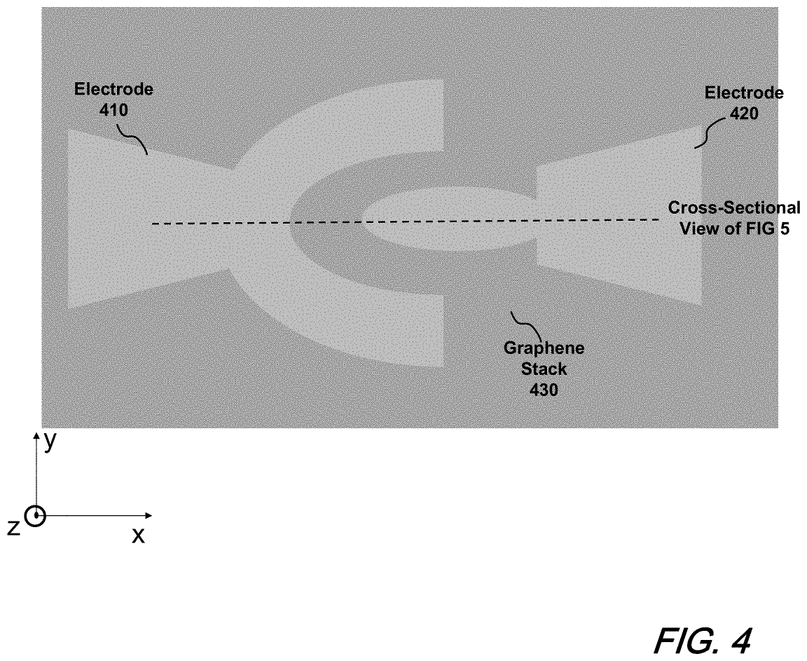

Such detectivity may be further enhanced by judicious design of the electrodes such that an antenna structure is formed. Turning our attention now to FIG. 4, there is shown a schematic diagram depicting a top view of a tunable graphene detector structure exhibiting a Corbino geometry including inner and outer electrodes according to aspects of the present disclosure. Shown in that figure are an inner/outer pair of complementary Corbino geometry electrodes (410, 420) which are physically and electrically separated by a graphene “stack” 430. When so configured, tunable graphene THz detector structures according to the present disclosure advantageously exhibit both fast response and wide bandwidth—in sharp contrast to contemporary bolometers that generally exhibit a bandwidth of <1 kHz. Demonstrating its manufacturability, FIG. 4(A) shows a photo-illustration of a top-view of a tunable graphene detector structure exhibiting a corbino geometry according to aspects of the present disclosure

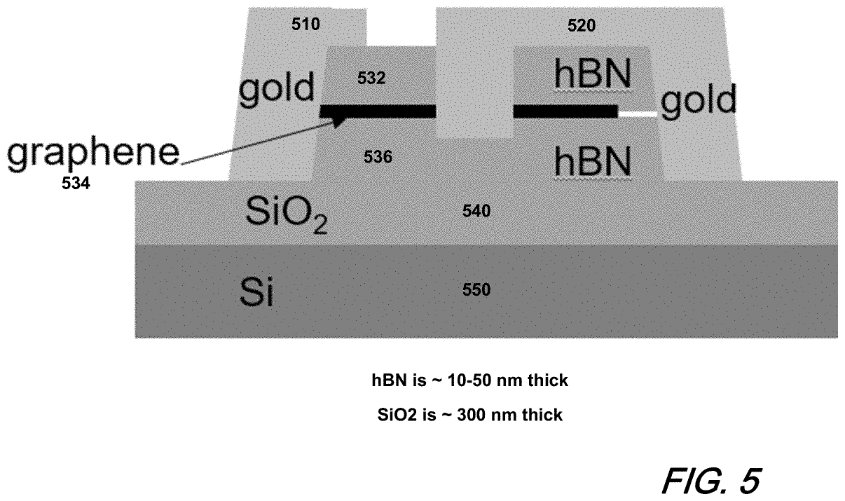

FIG. 5 shows a schematic cross-sectional view of a tunable graphene detector of FIG. 4 in which this cross-sectional view is taken along a dotted-line of that FIG. 4—according to aspects of the present disclosure. As shown in this figure, a tunable graphene detector according to aspects of the present disclosure may be advantageously constructed using familiar technologies and materials wherein a silicon substrate 550 has formed thereon a silicon dioxide SiO₂ layer on top of which is formed a graphene detector including a pair of gold (or other suitable conductive material) electrodes 510, 520 which are physically and electrically separate from one another by “graphene stack” including layers of hexagonal boron nitride (hBN) with a graphene monolayer interposed or “sandwiched” between the hBN layers. As previously described, when incident light of appropriate energy (THz) is directed onto the graphene stack, the graphene is transitioned from insulator to conductor and the structure may be used to detect such incident light (electromagnetic radiation).

We note that for the purposes of this illustrative structure, the hBN layers are ˜10-50 nm thick while the SiO₂ is −300 nm thick. Those skilled in the art will of course recognize that different particular geometries and thicknesses are contemplated within the scope of this disclosure.

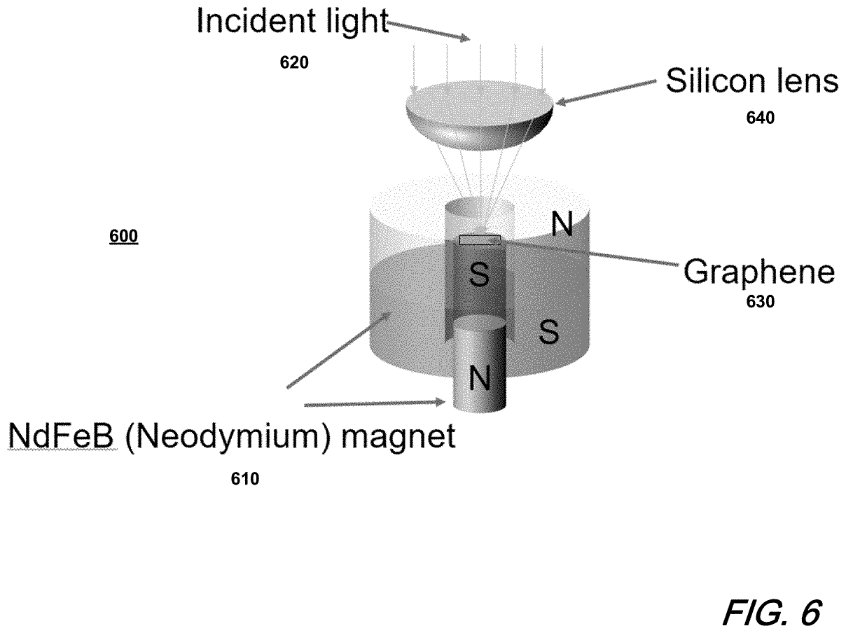

FIG. 6 shows a schematic diagram depicting an illustrative tunable graphene detector structure employing a permanent magnet according to aspects of the present disclosure. As shown this figure, a tunable graphene detector structure 630 such as that shown and described previously is positioned sufficiently proximate to a permanent magnet 610 such that the magnetic field produced by the magnet may influence/tune the Landau levels of the graphene.

As illustratively shown in this figure, the magnet may be a rare earth (NdFeB—Neodymium) magnet exhibiting a donut or ring or other suitable shape. When the magnet is moved relative to the graphene structure, the magnetic field influences/tunes the Landau levels of the graphene such that it is increasingly influenced by incident light of sufficient energy in the THz range. As shown further in this figure, the incident light may be advantageously directed to the graphene region in a more focused manner through the use of a silicon lens 640.

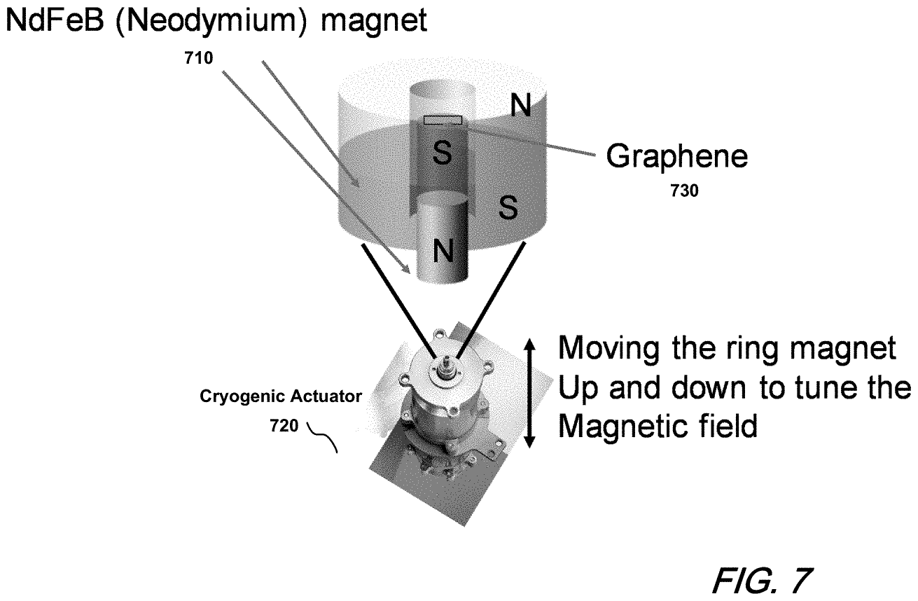

As those skilled in the art will readily appreciate, physically moving the magnet relative to the graphene structure may be performed by any of a number of actuator mechanisms. FIG. 7 shows a schematic diagram depicting an illustrative tunable graphene detector structure employing a permanent ring magnet 710 of FIG. 6 wherein the permanent ring magnet is moved relative to the graphene detector 730 via cryogenic actuator 720 according to aspects of the present disclosure. Moving the ring magnet relative to the graphene structure (i.e., up/down) alters/tunes the magnetic field acting upon the graphene.

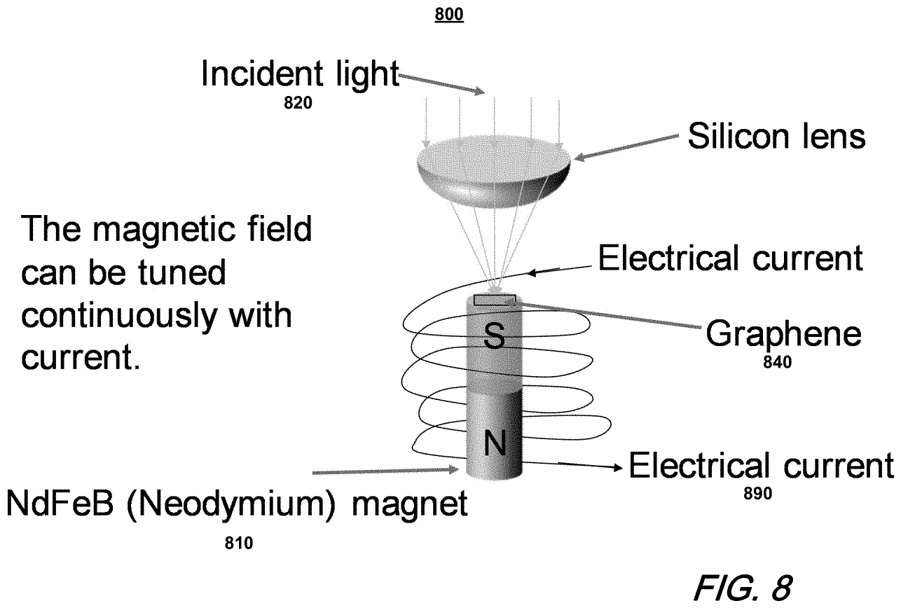

In a somewhat similar manner, a tunable graphene detector according to the present disclosure may be constructed including both superconducting coil magnet and a permanent magnet. FIG. 8 shows a schematic block diagram depicting an illustrative tunable graphene 800 detector structure employing a permanent magnet 810 and tunable coil magnet that is tunable by varying applied electrical current 890 according to aspects of the present disclosure. In this inventive manner, an electromagnet—which may advantageously be constructed via superconducting materials and methods, employs a variable electrical current through a conductive coil in conjunction with a permanent magnet to generate a variable/tunable magnetic field. While not specifically shown in this figure, the electromagnet may be included in a structure similar to that shown in FIG. 7, wherein the fixed magnet is movable to provide magnetic field tuning.

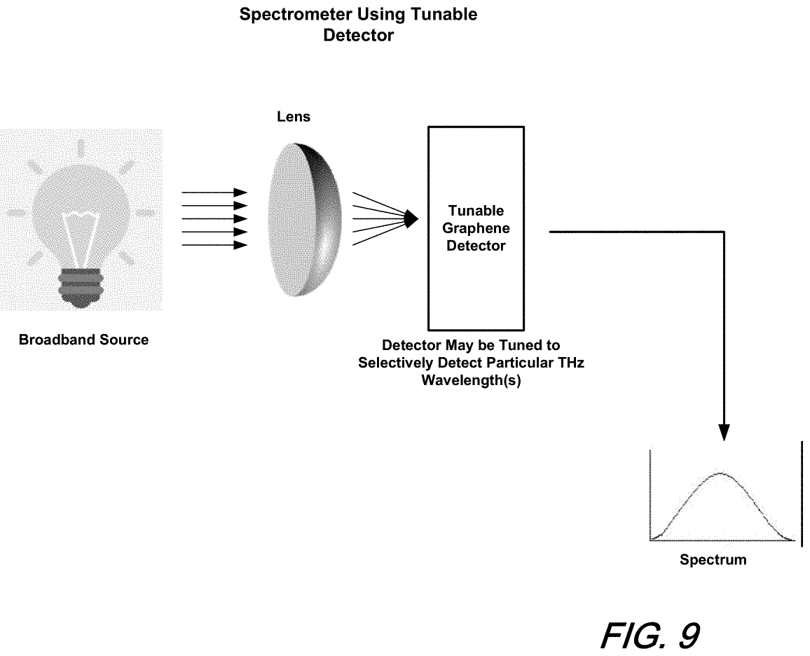

As should now be readily and understood by those skilled in the art in view of this disclosure, a spectrometer employing detector structures and methods according to the present disclosure may be constructed. FIG. 9 shows a schematic diagram of an illustrative spectrometer employing a tunable graphene THz detector according to aspects of the present disclosure. With reference to that figure it may be observed that a broadband source of radiation—including THz radiation—may be advantageously employed and such radiation may be focused through the effect of a lens structure to a tunable graphene detector as shown and described herein. Advantageously, the detector may be tuned as described previously by varying combinations of applied voltage an applied magnetic field such that a particular wavelength is detected. From such detection(s), a spectrum or other output may be generated as desired. While not specifically shown in this figure, an optional “sample” may be positioned prior to the detector such that said sample's absorption/transmittance characteristics may be determined as well.

With this disclosure in place, we may now illustrate some operational/experimental results of systems, methods, and structures constructed according to aspects of the present disclosure.

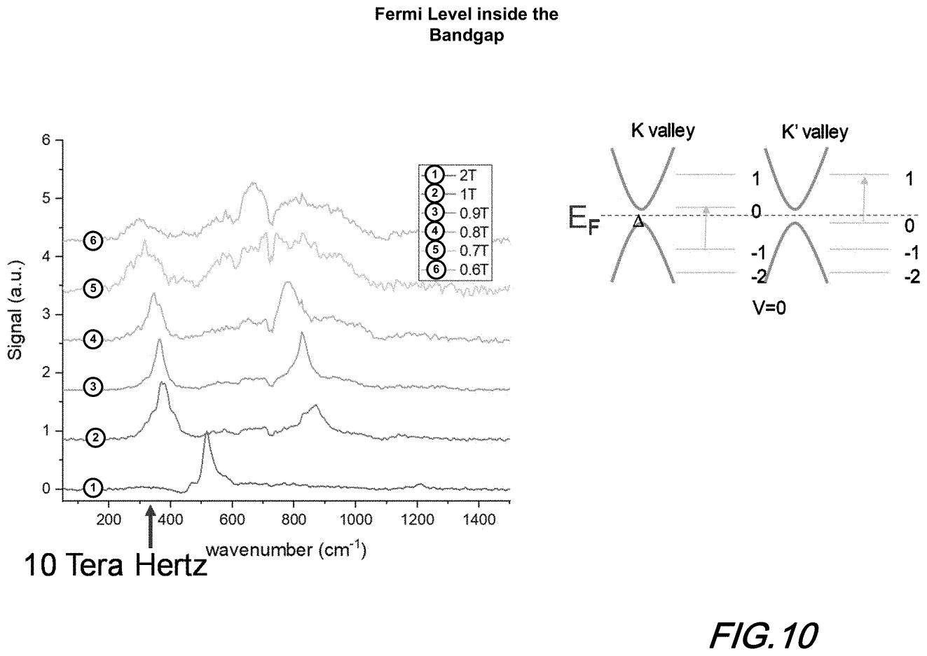

FIG. 10 shows a plot of Signal (a.u.) vs. wavenumber (cm⁻¹) illustrating Fermi level inside a bandgap according to aspects of the present disclosure.

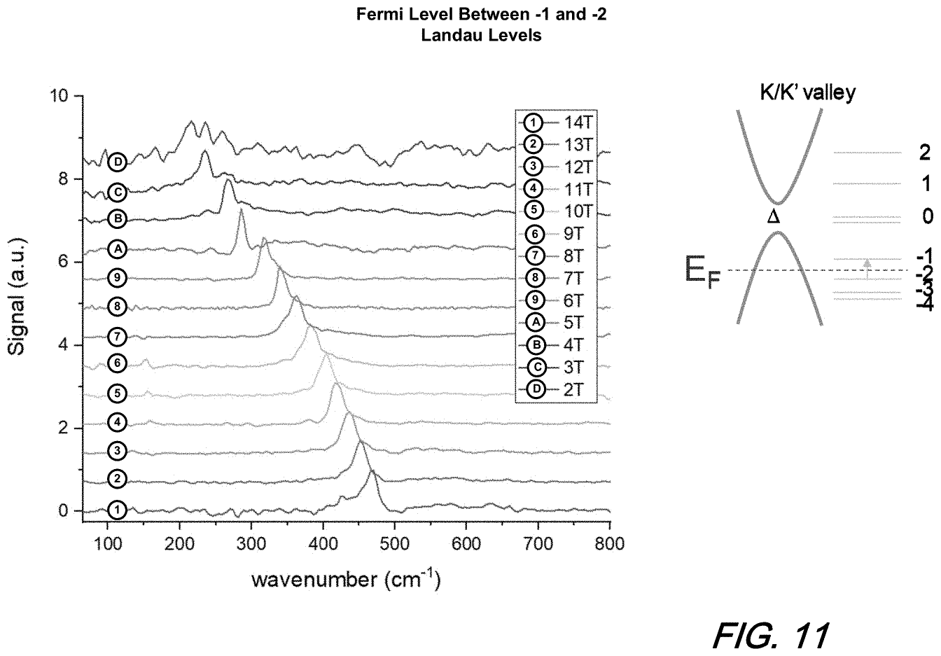

FIG. 11 shows a plot of Signal (a.u.) vs. wavenumber (cm⁻¹) illustrating Fermi level between −1 and −2 inside a bandgap according to aspects of the present disclosure.

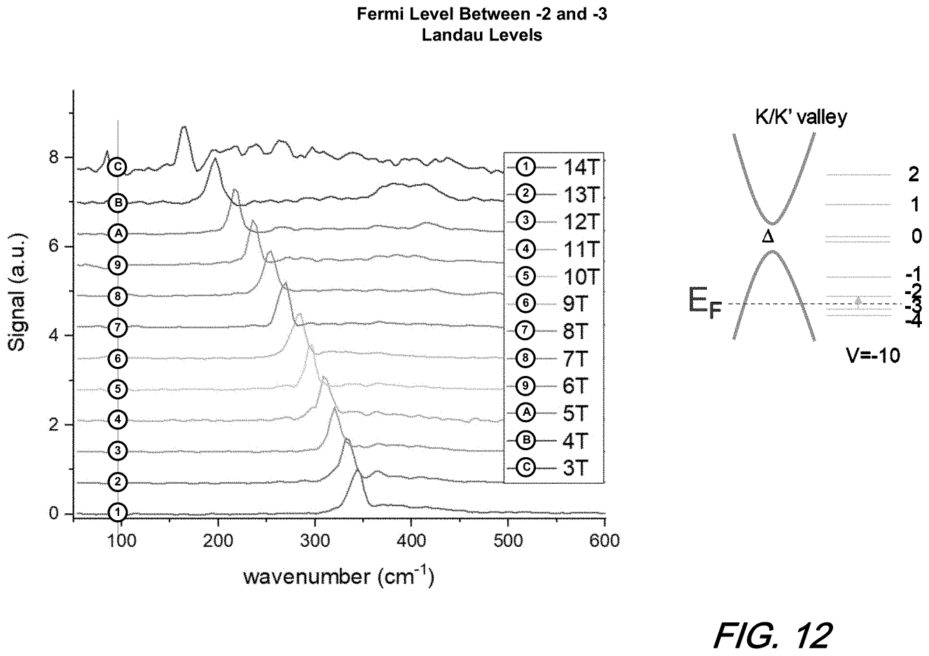

FIG. 12 shows a plot of Signal (a.u.) vs. wavenumber (cm⁻¹) illustrating Fermi level between −2 and −3 inside a bandgap according to aspects of the present disclosure.

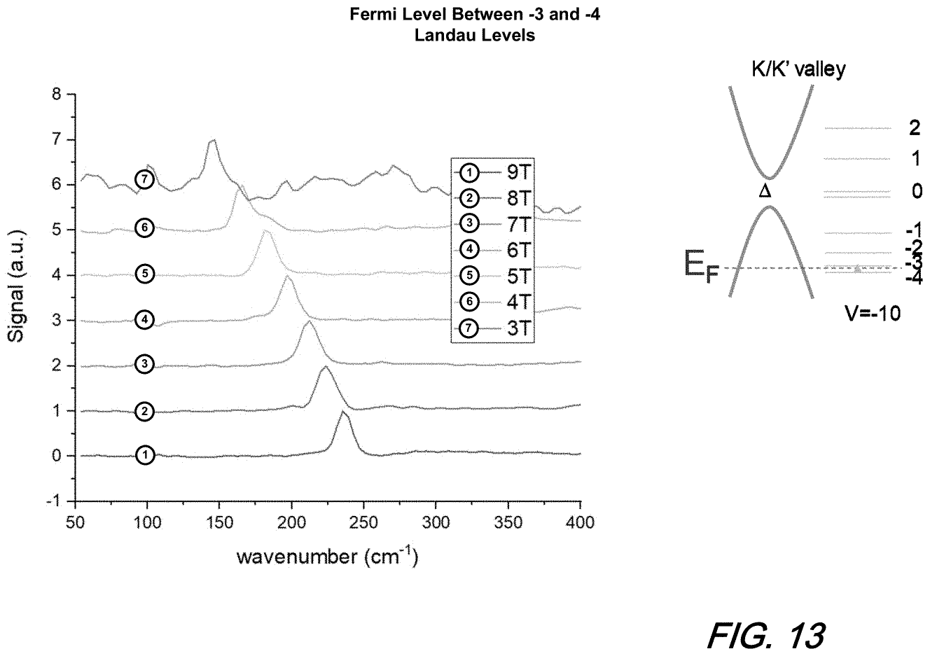

FIG. 13 shows a plot of Signal (a.u.) vs. wavenumber (cm⁻¹) illustrating Fermi level between −3 and −4 inside a bandgap according to aspects of the present disclosure.

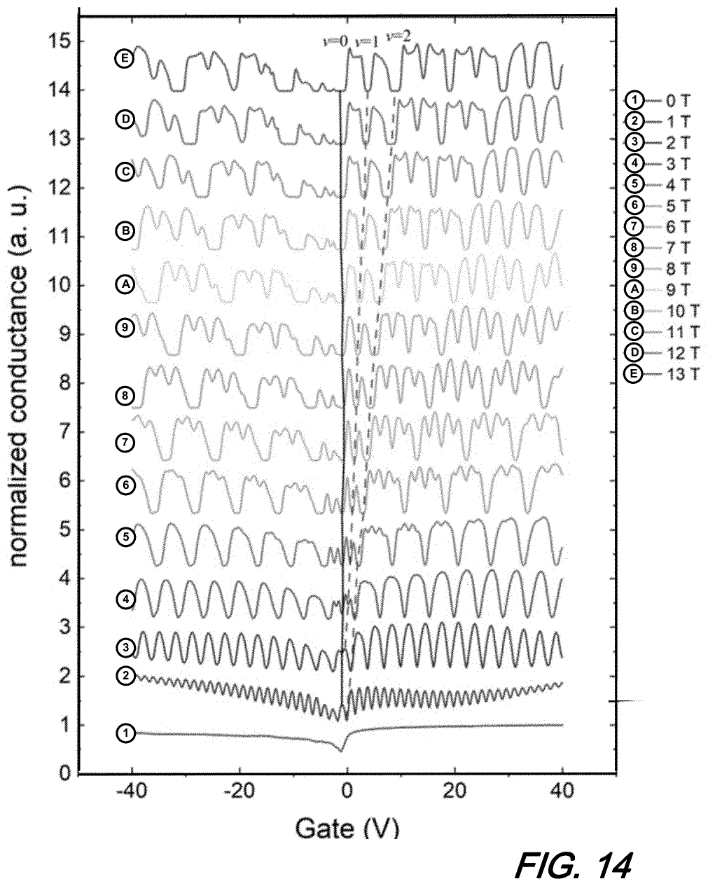

FIG. 14 shows a plot of normalized conductance (a.u.) vs. Gate (V) illustrating the development of Landau levels at magnetic field levels less than 1 Tesla according to aspects of the present disclosure.

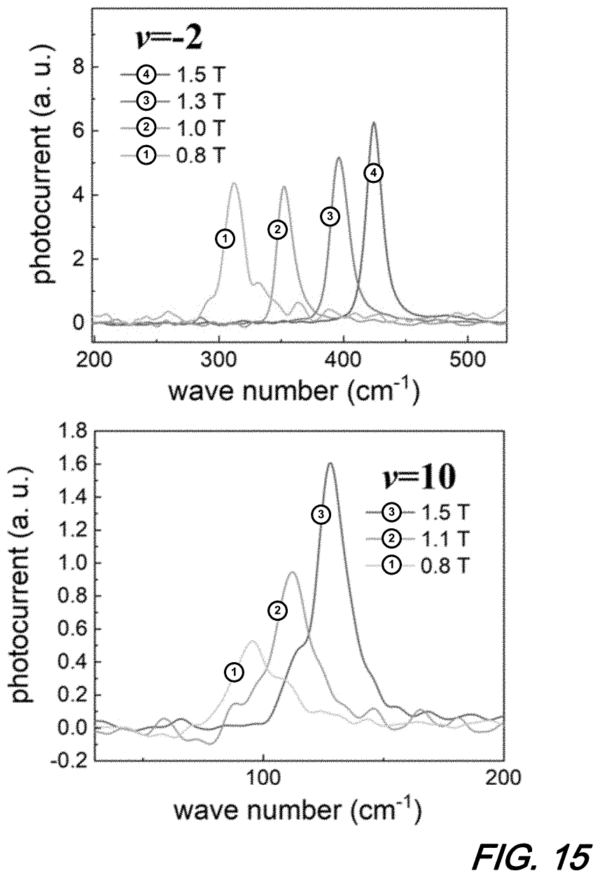

FIG. 15 shows a pair of plots of photocurrent (a.u.) vs. wave number (cm⁻¹) for v=−2 and v=10 according to aspects of the present disclosure.

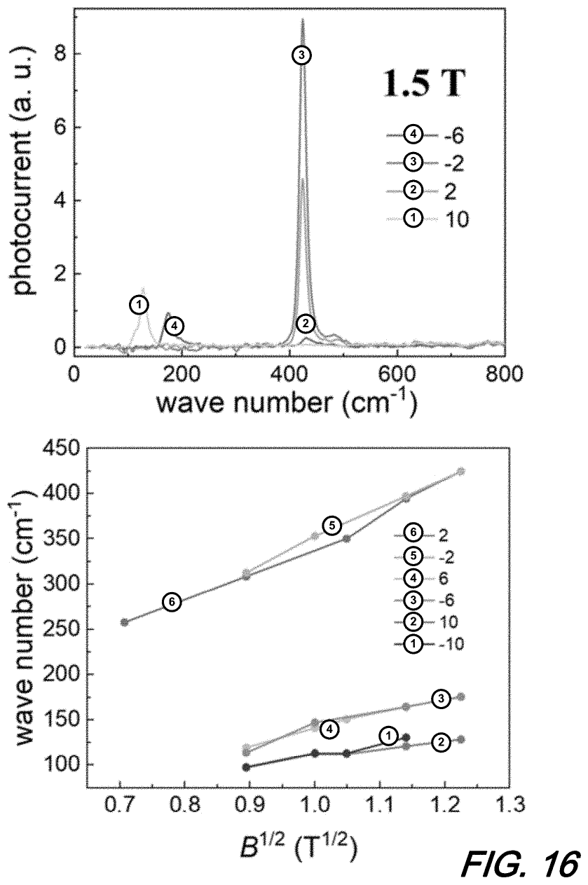

FIG. 16 shows a pair of plots of (upper) photocurrent (a.u.) vs. wave number (cm⁻¹) and (lower) wave number (cm⁻¹) vs. B^{1/2} (T^{1/2}) according to aspects of the present disclosure.

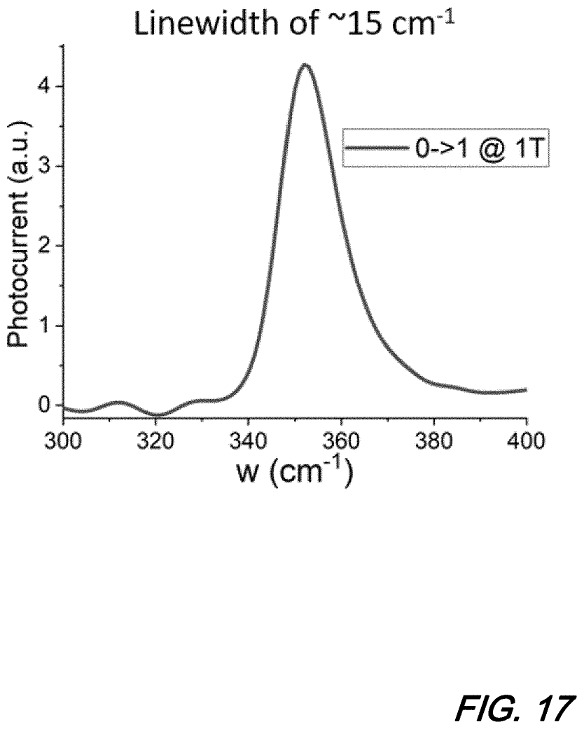

FIG. 17 shows a plot of photocurrent (a.u.) vs. W (cm⁻¹) illustrating the nearly Lorentzian linewidth FWHM˜1.6 meV, limited by lifetime, not disorders according to aspects of the present disclosure.

At this point, those skilled in the art will readily appreciate that while the methods, techniques, and structures according to the present disclosure have been described with respect to particular implementations and/or embodiments, those skilled in the art will recognize that the disclosure is not so limited. Accordingly, the scope of the disclosure should only be limited by the claims appended hereto.

1. A tunable graphene detector structure comprising:
a substrate having formed thereon;
a source electrode, a drain electrode, and a gate electrode; and
a graphene layer interposed between the electrodes;
a magnet configured to be movable relative to the graphene.

2. The tunable graphene detector structure according to claim 1 further comprising:
an antenna structure formed from the source and drain electrodes.

3. The tunable graphene detector structure according to claim 2 wherein the antenna structure is configured to receive terahertz (THz) radiation.

4. The tunable graphene detector structure according to claim 3 wherein the antenna structure exhibits a Corbino geometry.

5. The tunable graphene detector structure according to claim 1 wherein the movable magnet is moved via linear actuator mechanism.

6. The tunable graphene detector structure according to claim 1 wherein the movable magnet includes a movable part and a fixed part.

7. The tunable graphene detector structure according to claim 6 wherein the fixed part is configured as a ring and the movable part is configured as a rod that moves within the fixed ring.

8. The tunable graphene detector structure according to claim 1 wherein the graphene layer is included in a graphene stack, said stack having the graphene layer interposed between layers of boron nitride (hBN).

9. The tunable graphene detector according to claim 1 wherein the hBN stack is 10-50 nm thick.

10. A method for detecting terahertz (THz) radiation by a field-effect transistor (FET) structure having a graphene structure interposed between a source electrode and a drain electrode of the FET structure, said method comprising:
exposing the graphene structure to a source of THz radiation; and
applying a magnetic field to the FET structure; and
varying the applied magnetic field.

11. The method according to claim 10 further comprising:
varying an applied electrical potential to the FET structure.

12. The method according to claim 11 further comprising:
measuring a current between source and drain electrodes.

13. The method according to claim 10 further comprising:
moving a permanent magnet relative to the graphene structure to vary the applied magnetic field.

14. The method according to claim 10 further comprising:
varying an electrical current to an electromagnet to vary the applied magnetic field.

15. The method according to claim 10 wherein a portion of the magnetic field is generated by a Rare Earth magnet exhibiting a ring shape and the varying magnetic field is generated by moving another Rare Earth magnet relative to the ring shaped magnet.

16. The method according to claim 10 further comprising:
directing the THz radiation to the graphene structure through the effect of a lens structure.

17. The method of claim 14 wherein the electromagnet is a Rare Earth magnet.

18. The method of claim 14 wherein the applied magnetic field is generated by the electromagnet and a permanent magnet.

19. The method of claim 18 further comprising:
varying the applied magnetic field by tuning the electromagnet; and
varying the applied magnetic field by moving the permanent magnet.
wherein the electromagnet and the permanent magnet each include one or more Rare Earth Elements.

20. A THz spectrometer comprising:
a broadband source of THz radiation; and
a graphene detector configured to respond to received THz radiation, said detector tunable by varying at least one of applied magnetic field and an applied electrical potential.
